(19) United States
(12) Patent Application Publication
(10) Pub. No.: US 2025/0237531 A1
(43) Pub. Date: Jul. 24, 2025

(54) NON-CONTACT INDUCTIVE SWITCH

(71) Applicant: AZOTEQ HOLDINGS LIMITED, Nicosia (CY)

(72) Inventors: Frederick Johannes BRUWER, Paarl (ZA); Frederick Johannes BRUWER, JR., Paarl (ZA)

(21) Appl. No.: 19/035,221

(22) Filed: Jan. 23, 2025

(30) Foreign Application Priority Data
Jan. 24, 2024 (ZA) 2024/00806

(51) Int. Cl. G01D 5/20; G01D 5/14; G06F 3/02; G06F 3/0362

(52) U.S. Cl. CPC G01D 5/20; G01D 5/145; G06F 3/0202; G06F 3/0362

(57) ABSTRACT

The use of inductive and Hall effect measurements to allow a movement and displacement-based user interface to be implemented without requiring electrical connections to the inside of a sealed product housing.

### CROSS-REFERENCE TO RELATED APPLICATION

The present application claims the benefit of South African Provisional Patent Application No. 2024/00806, filed on Jan. 24, 2024, the content of which is hereby incorporated by reference into this application.

### BACKGROUND

The use of electromechanical switches is commonplace. Many applications have a switch interface outside on a product housing with electronics inside the product housing. A number of these applications concern products exposed to water or other liquids where some form of sealing is required. The transfer of switch movement from outside the housing to inside the housing is always a cost issue and a reliability issue in terms of liquid ingress.

### SUMMARY

It is an objective of this invention to provide a cost effective and reliable solution to seal a product's internal space (electronics etc.) from the outside world but still have user interface switches that are activated through pressure/displacement on the outside.

This invention will alleviate the requirement to transfer either electronic connections or movement from inside to outside through a sealed construction.

This invention is described using multiple inductive technology phenomena as a basis for recognizing switch actuation (movement and switching).

The advantage of the inductive solution according to this invention compared to capacitive sensing switch solutions is that liquids have no effect, and the user can wear gloves for example.

In a first embodiment an interfering member outside a housing is used to move into a core of an inductor coil which is inside the housing to influence the inductance of said coil. If the interfering member is a ferrite material the inductance will increase. If it is metal the inductance will decrease due to losses from eddy currents forming in the interfering member. Based on the displacement to inductance ratios, an inductance can be chosen as a threshold for a decision that switch activation was achieved.

If a slit is made in the interfering member two opposing parts are formed. The threshold can be detected by a comparator or equivalent device. Where appropriate a signal from the comparator can be applied to a suitable mechanism, which may include a processor, to implement a response to the switch signal inside a housing.

If a conventional push button switch is used to galvanically connect the two sides (parts) of the slit, the closure of the switch will result in an abrupt change in the inductance of the coil. This allows an easy detection, through inductance measurement, of the exact moment the switch is closed. The switch can provide tactile user feedback. Tactile user feedback can also be implemented by using haptic signal generators such as drivers and LRA's or a simpler mechanical construct. It is important to align the switching point with the “click” generation.

In another embodiment of the invention, a flat layer acting as an interfering member is placed adjacent to an inductive coil that is for example formed with tracks on a printed circuit board (PCB). Moving the flat interfering member closer to the PCB inductor will reduce the inductance of the said inductor due to eddy currents formed in the interfering member and losses associated with these eddy currents. This action is good to show the user is in contact with the switch.

As described hereinbefore, a threshold event corresponding to switch activation can be chosen.

In a variation, the interfering member can be used in combination with an electromechanical switch. The electromechanical switch does not need to be connected to the electronics inside the product (in the housing) and operates normally to provide the switch function and tactile feeling. The interfering member is made as two strips that are connected together at one end, with the switch opening or closing a connection between the strips at the other end.

When this modified interfering member approaches the inductor, the inductance is also changed in a manner which is related to the change in distance between the interfering member and the inductor. However, when the switch is activated (closed) the change in inductance is substantial, even without any change in distance between the interfering member and the inductor. This is because when the switch is closed an electrical path is formed that allows substantially more flow of eddy currents.

Thus, one method to change inductance is purely based on separation between the interfering member and the inductor coil and another method is to increase the capability of the interfering member to generate eddy currents.

The sensor arrangement may detect user force application before the threshold level is reached i.e. before production of an output signal which happens when the threshold level is reached.

In accordance with the description above a product can have a completely sealed surface area, formed by an enclosing housing, and still have a user interface based on electromechanical switches.

In accordance with the invention a magnet can be coupled to a rotatable knob that can also be pressed for switch actuation. The magnet rotation can be measured with Hall effect (or other sensors) inside the product housing without any type of physical/electrical contact required.

Light guides can be formed using translucent material to guide light signals from the LED's inside the product housing to the user interface outside.

The switch module (without rotation) may be a sealed unit, for example the interfering member and the switch can be molded with a compressible compound which prevents the ingress of liquids.

In one embodiment the invention provides a user interface device for a product inside a housing, said interface device comprising an inductor coil inside the housing, an actuator outside the housing, an interfering member, outside the housing, which is movable relative to the coil by application of a user force on the actuator, whereby said movement of the interfering member produces a change in the inductance of the coil, and a sensor arrangement inside the housing which senses the inductance of the coil and which, in response to a predetermined change in the inductance, produces an output signal.

Said predetermined inductance change may correspond to a threshold inductance value.

The actuator may be a knob, a button or any other suitable device to apply force, directly or indirectly, on the interfering member.

### BRIEF DESCRIPTION OF DRAWINGS

FIG. 1a—Inductive measurement using an interfering member entering the core of an inductor and to recognize the closing of a switch.

FIG. 1b—Inductive detection of switch actuation.

FIG. 2a—Inductive detection of switch actuation.

FIG. 2b—Interfering member construction.

FIG. 3—Inductive detection of contact with switch and also of switch closure.

FIG. 4a—Interfering member adapted for switch closure detection and Hall rotation measurement.

FIG. 4b—Inductive detection of displacement and of switch closure with magnetic measurement of switch knob rotation.

FIG. 5—Optical indications.

### DETAILED DESCRIPTION OF DRAWINGS

The description that follows is aimed at clarifying the methods and implementations in accordance with this invention in an exemplary manner and it is not meant to be exhaustive or limiting.

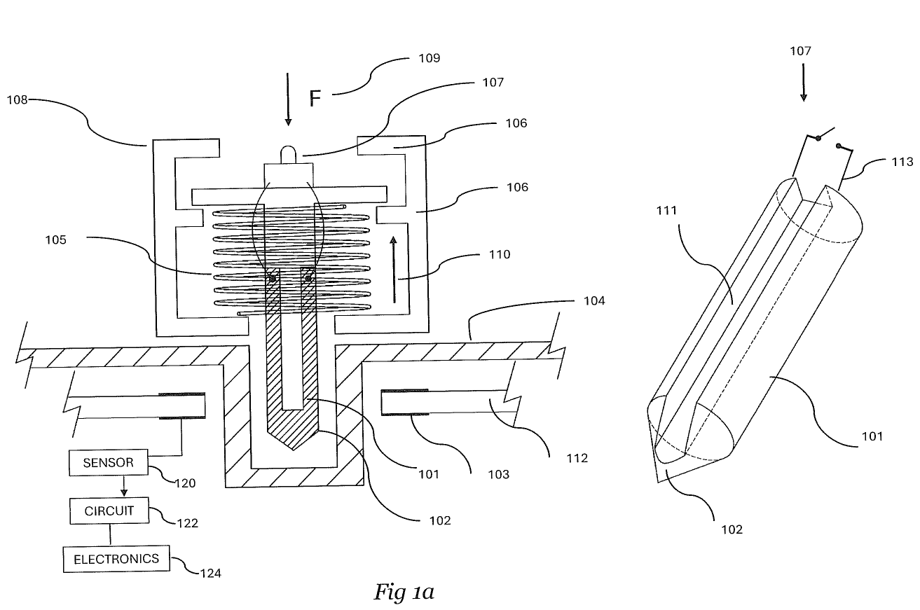

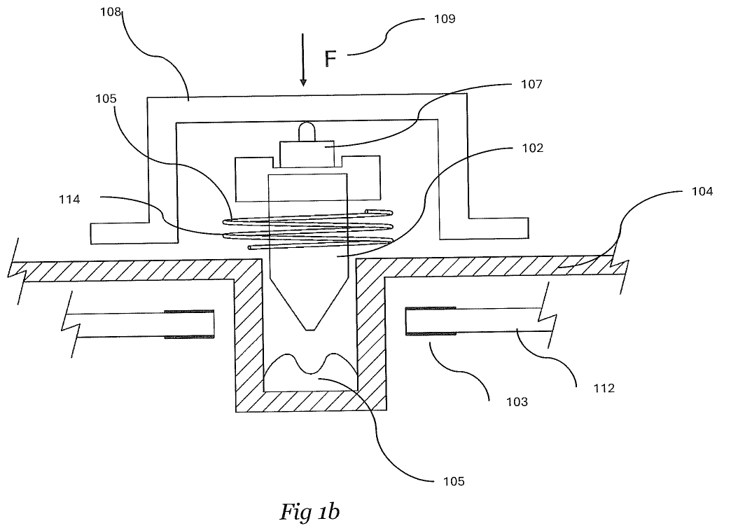

In FIG. 1a the method of using an interfering member entering the core of an inductor is shown. A switch module must be fixed to an outer side of a housing 104 of the product 124 (inside the housing) and an aesthetic or appropriate switch top may be selected.

An actuator for moving the interfering member is outside the housing. The actuator can take on many different forms but conveniently is presented to a user as a part of an external switch, as is described hereinafter and shown in the drawings, e.g. a knob, a button, a dial or other user actuable component.

The interfering member 102 is in this case a single part that also forms a rod 101 that the user pushes down. The rod 101 may for example be plastic with a metal or ferrite part attached to a bottom tip of the member 102.

As the user pressure produced, by a user force (F) on an actuation, overcomes the back pressure 110 of a spring 105, the interfering member 102 fills more of the space in a core of a coil 103 inside the housing 104. The more it fills the space, the more it affects the inductance of said coil 103 that is for example formed with tracks on a PCB 112.

A switch module housing 108 contains a switch 107 and has blocks 106 for keeping the rod 101 and interfering member 102 within a movement range. The spring 105 presses back (110) against the user pressure and pushes the rod back when user pressure is released.

The product housing 104 is solid and sealed. In this implementation an arbitrary level can be chosen as a level at which a decision will be made that the switch 107 is actuated. Feedback to the user about the switch selection can be through the function selected being activated, through visible indications or haptic feedback. The switch 107 is available to a user as an actuator, as referred to hereinbefore.

The inductance of the coil 103 is monitored by a suitable sensing device or comparator 120 and upon sensing a threshold level a signal is applied to a circuit 122 which is designed or programmed to implement the switch selection, possibly by initiating a process which simulates or is identical to what would occur if the switch 107 had been connected directly, in a conventional manner, on or in an electronic device or circuit 124 inside the housing 104.

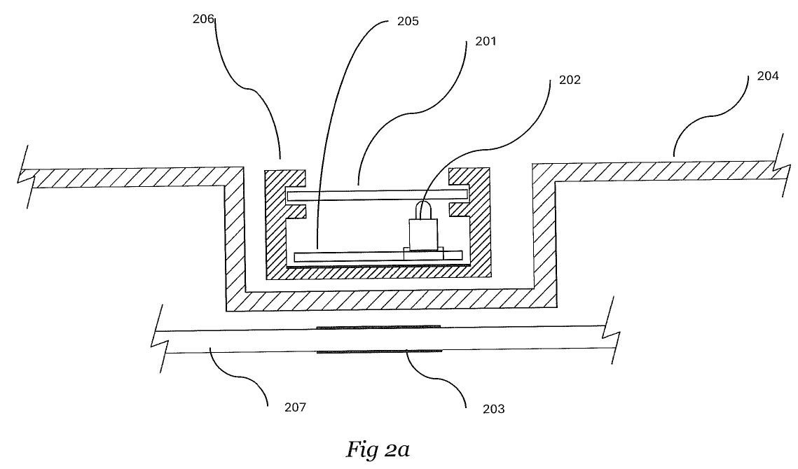

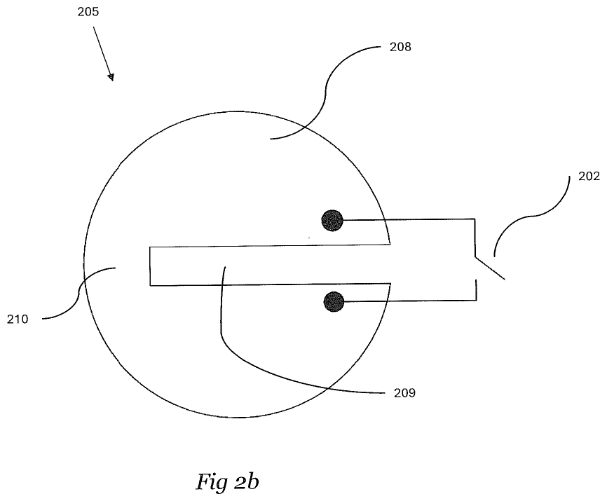

In another embodiment the decision for deciding on the switch 107 being closed is done through inductive sensing. The switch 107 is connected (113) to the two sides of a slit 111 where said slit cuts through a cylindrical interfering member 102 on one side-see insert drawing in FIG. 1a. (FIG. 2b is an end view of a similar construction for an interfering member 205) When the switch 107 is closed under pressure 109 exerted by a user, the effect of eddy currents increases and the inductance of the coil 103 is instantly reduced. This abrupt change in inductance can be seen in the inductive measurements done inside the product housing and the closure of the switch 107 (which corresponds with the switch's tactile feel) can be clearly recognized.

In FIG. 1b another method is shown to detect contact with a switch module housing 108 by a user exerting a force 109 (F) that overcomes the spring 105 and moves the interfering member 102 deeper into the core of the inductive coil 103 thereby affecting the measurable inductance of the inductor 103 that is positioned inside the housing 104 which seals off the product 124 (FIG. 1a) from the outside environment. An inductive coil 114 includes a number of windings around the member 102. Ends of the windings are free, i.e. not connected to any component.

At one point the more pressure by the user applied to the switch module 108 results in the electromechanical switch 107 closing (click) and shorting out (connecting together) the two ends of the coil 114. The interfering member 102 and the two inductors 103, 114 form a transformer i.e. there is electromagnetic coupling between the coils 103, 114 and the member 102. The connection of the ends of the winding 114 affects the measurable inductance/impedance of the inductor 103 which is sensed in the described manner. There is still no requirement for any electromechanical connections between the switch module and the electronics inside the product contained in the product housing 104.

In FIG. 2b the design of another interfering member 205 (as per the member 102) is shown. A metal layer 208 is largely divided into two parts by a slit 209 although a connection 210 between the parts is maintained on one side. A switch 202 to electrically connect the two parts at the open side is placed on the other (open) side. The connection is preferably beyond the halfway point.

In FIG. 2a the interfering member 205 of FIG. 2b is fitted into (attached to) a switch module 206 at a bottom of the module. Said switch module 206 can be positioned outside a sealed product housing 204. A conventional push button switch 202 is positioned to be in contact with a user press layer 201 of the switch module.

The interfering member 205 is within the inductive field of an inductor 203 that is inside the product housing. The inductor 203 can be formed by conductive tracks on a PCB 207.

When the user exerts pressure on the press layer 201, force is exerted on the switch 202. When the switch “clicks” the circuit is closed and eddy current can flow in the bigger area resulting in an immediate substantial change in the measured inductance. The switch 202 gives tactile feedback to the user and the change in inductance is perfectly aligned with the switch actuation.

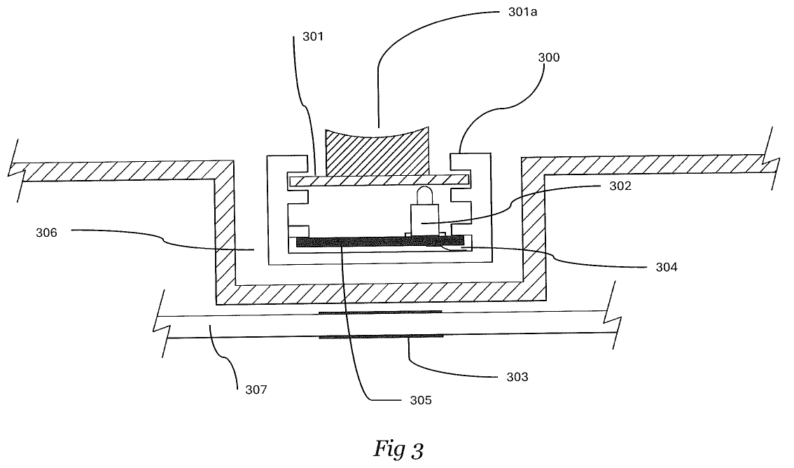

In FIG. 3 an implementation is shown that detects user contact with a switch module press layer 301, 301a and uses inductive measurements to detect when a push button switch 302 is “clicked”.

An interfering layer 305, which could be similar in design to the layer 205 of FIG. 2b, is fitted to be slightly pushed away from the bottom of a switch module 300 using a spring 304. The switch pressure layer 301 is modified to show a typical option 301a. When the user touches the switch press layer 301a the pressure first overcomes the spring 304 and the interfering layer 305 (with the switch open) moves closer to the inductor 303 and, as such, affects the inductance of the inductor 303 to allow detection of the user touch.

After a small displacement, the interfering layer 305 is in contact with the bottom housing of the switch and further pressure from the user will compress the switch 302 until it “clicks”. The closure of the switch that corresponds to the tactile feel is detected through the inductive measurements (implemented as described and as per FIG. 2b).

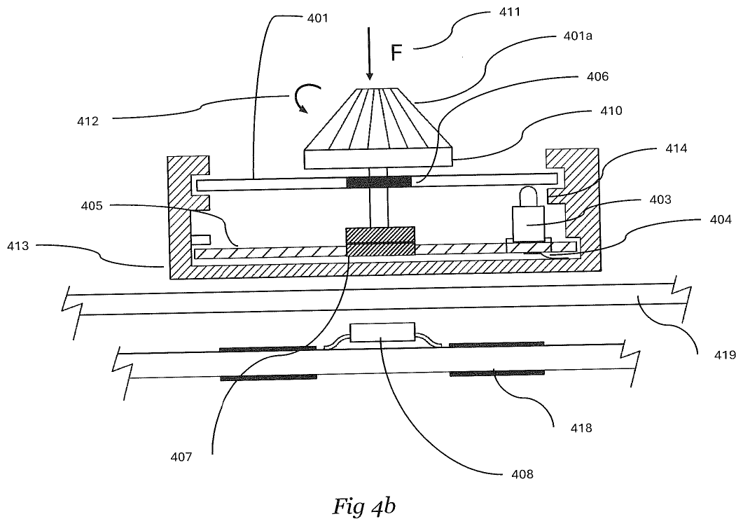

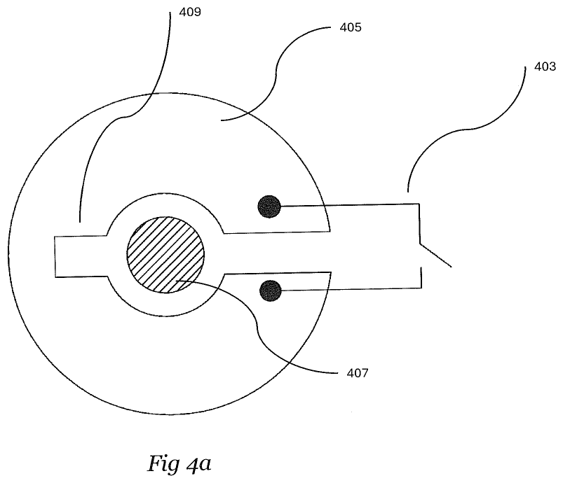

In FIGS. 4a and 4b a switch implementation in accordance with this invention is described that offers contact detection (inductive), switch actuation detection (inductive), and z-axis (horizontal) rotation measurement, using a magnet and Hall effect sensing.

In FIG. 4a an exemplary interfering member 405 is shown with a slit 409 and a switch 403 to short two parts formed by, and bounding, the slit 409. The slit 409 is shaped to allow for positioning of a magnet 407 that can rotate.

In FIG. 4b an exemplary switch construction is shown with a knob 401a mounted onto the press layer 401. The knob can be pressed with a force F in a direction 411 and is mounted in a way that facilitates horizontal (or z-axis) rotation 412.

When pressing the knob 401a in the direction 411 the force F is transferred through a mounting mechanism 406 onto the press layer 401 and then via the switch 403 onto the interfering member 405. First the spring 404 must collapse until the interfering member is pushed onto the bottom of a switch module 413, or stopped by a blocking mechanism 414 to prevent damage to the spring 404. Further force will be absorbed by the switch 403 until it “clicks”. Thereafter further force will push the press layer 401 against the blocking mechanism 414. A change in inductance in a coil 418 inside the product housing 419 results.

The knob can have a dial indication 410 to indicate its rotational position. Rotating the knob 401a will correspond to rotation of the magnet 407 at the bottom of the switch module. The magnet position is measured using a Hall effect sensor 408 that is mounted inside the product housing 419—sealed from the environment. A signal from the sensor 408, which is dependent on the magnet orientation, is applied to a circuit (not shown) which is similar to the circuit 122.

The product housing is totally sealed from the outside world for air and liquids. No seals or bushes to allow kinetic movement or any displacement are required in the product housing.

Apart from tactile user feedback from the switch 403, the product may have haptic, light or sound feedback.

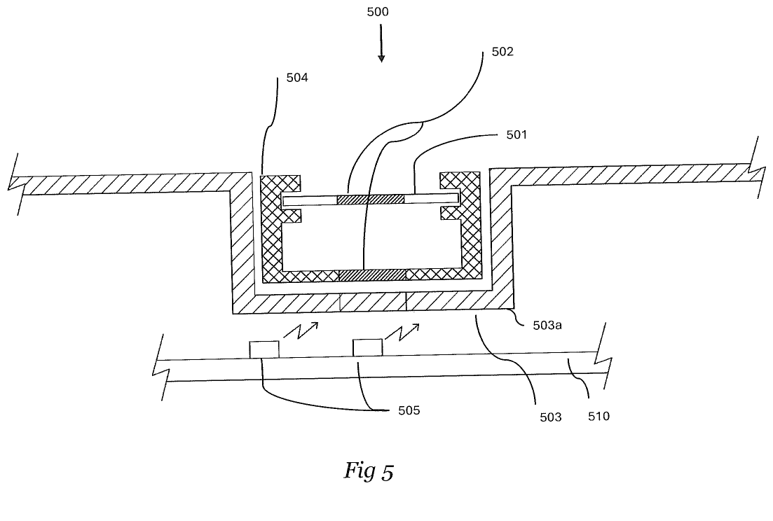

In FIG. 5 a switch module 500 is shown with parts of the module housing 503 being translucent. This will allow light indications of various kinds (color or patterns) onto the switch module surface.

A bottom part 503a of the housing may be translucent, and sides 504 of the switch module or center parts 502 thereof may also be translucent. This will allow LEDs 505 on a PCB 510 inside the product housing to provide visible indications on the surface of the switch module. The sides 504 may be used as light pipes or light guides.

The cover, form and fixing of the switch module to the product housing have not been addressed in detail and depend on individual products. The switch module in accordance with this invention can now be a hot swappable item.

1. A user interface device for a product inside a housing, said interface device comprising an inductor coil inside the housing, an actuator outside the housing, an interfering member, outside the housing, which is movable relative to the coil by application of a user force on the actuator, whereby said movement of the interfering member produces a change in the inductance of the coil, and a sensor arrangement inside the housing which senses the inductance of the coil and which, in response to a predetermined change in the inductance, produces an output signal.

2. The user interface device of claim 1 wherein the actuator comprises or is included in a switch module.

3. The user interface device of claim 2 wherein the switch module includes a switch and said output signal is produced upon closure of the switch by said application of the user force.

4. The user interface device of claim 1 wherein the actuator is a knob, button, or other user actuable component.

5. The user interface device of claim 1 wherein said sensor arrangement detects said application of the user force which changes said inductance of the coil before production of said output signal.

6. The user interface device of claim 1 wherein the switch module comprises a knob and a magnet which is movable by movement of the knob, and wherein said sensor arrangement includes, inside the housing, a Hall effect sensor which detects orientation of the magnet relative to the housing.

7. The user interface device of claim 1 wherein the interfering member comprises at least two parts which are connected to each other upon said application of the user force, such that the effect of eddy currents in the interfering member is increased.

8. The user interface device of claim 2 wherein the switch module includes a switch and a winding with a first end and a second end and wherein upon closure of the switch due to application of said user force, said first end is connected to said second end and, due to electromagnetic coupling between the winding, the coil and the interfering member, the inductance of the coil is varied.

9. The user interface device of claim 2 wherein the switch module is moulded using a compressive compound into a single sealed unit to provide a seal against the ingress of liquids.

10. The user interface device of claim 1 wherein the product is sealed inside the housing.

11. A method of implementing a user interface for a product which is inside a housing, the method including the steps of locating an inductor coil inside the housing, causing an interfering member, outside the housing, to move relative to the coil by application of a user force to an actuator outside the housing thereby to produce a change in the inductance of the coil, monitoring the inductance of the coil, and in response to a predetermined change, in the inductance of the coil, of producing an output signal inside the housing.

12. The method of claim 10 which includes the step of monitoring the inductance of the coil thereby to detect said application of the user force on the actuator prior to the production of said output signal.

13. The method of claim 10 wherein the interfering member includes a first part and a second part and wherein the method includes the step of connecting the first part to the second part thereby to increase the effect of eddy currents in the interfering member as it is moved relative to the inductor coil.

14. The method of claim 10 which includes the steps of using a Hall effect sensor to detect orientation of a magnet which is outside the housing, which is attached to the actuator and which is movable by the actuator, and of producing, inside the housing, a signal which is dependent on the orientation of the magnet.
